(19) United States
(12) Patent Application Publication
(10) Pub. No.: US 2025/0370032 A1
(43) Pub. Date: Dec. 4, 2025

(54) SEMICONDUCTOR SYSTEM THAT DYNAMICALLY ADJUSTS OPERATING VOLTAGE

(71) Applicant: Samsung Electronics Co., Ltd., Suwon-si (KR)

(72) Inventors: Juyeon LEE, Suwon-si (KR); Sungcheol PARK, Suwon-si (KR)

(73) Assignee: Samsung Electronics Co., Ltd., Suwon-si (KR)

(21) Appl. No.: 18/958,575

(22) Filed: Nov. 25, 2024

(30) Foreign Application Priority Data
May 31, 2024 (KR) 10-2024-0072042

(51) Int. Cl. G01R 31/28; H03K 3/03

(52) U.S. Cl. CPC G01R 31/2856; H03K 3/0315

(57) ABSTRACT

A semiconductor system that includes a core die including a memory cell; a host die electrically connected to the core die; and a power management integrated circuit that provides an operating voltage to the core die. The host die includes a self-test circuit that performs a self-test on the memory cell at one or more voltage levels according to a test pattern and outputs a self-test result based on the self-test, in response to receiving a boot signal; and a processor that determines a minimum operating voltage of the core die based on the self-test result.

### CROSS-REFERENCE TO RELATED APPLICATION

This application claims priority to Korean Patent Application No. 10-2024-0072042, filed in the Korean Intellectual Property Office on May 31, 2024, the entire contents of which are hereby incorporated by reference.

### BACKGROUND

The present disclosure relates to semiconductor systems.

Memory devices in electronic systems are typically designed to be capable of high-capacity data storage. As memory devices have become more highly integrated with higher storage capacity, power consumption of the memory devices has increased. Accordingly, it may be advantageous to reduce the power consumption of the memory devices.

In general, the minimum operating voltage of memory devices is determined by testing samples (e.g., corner samples) in the test operation of the memory device manufacturing process (post-process). Various margins considering various factors such as process variation margin, temperature margin, aging margin and/or voltage drop margin are added to the determined minimum operating voltage to determine the operating voltage of the memory device. The operating voltage determined in this way is fixed and used after completion of manufacturing (after fab out), that is in actual use.

However, since the operating voltage includes various margins, there may be a problem that a voltage higher than a voltage actually required for the operation of the memory device may be used, thus consuming more power.

### SUMMARY

Some example embodiments of the inventive concepts provide a semiconductor system that dynamically adjusts operating voltage provided to a core die to reduce and/or minimize power consumption to overcome the above noted problems and/or other problems not explicitly described herein.

Some example embodiments of the inventive concepts provide a semiconductor system that includes a core die including a memory cell; a host die electrically connected to the core die; and a power management integrated circuit that provides an operating voltage to the core die. The host die includes a self-test circuit that performs a self-test on the memory cell at one or more voltage levels according to a test pattern and outputs a self-test result based on the self-test, in response to receiving a boot signal; and a processor that determines a minimum operating voltage of the core die based on the self-test result.

Some example embodiments of the inventive concepts further provide a semiconductor system that includes a core die including a memory cell; a buffer die electrically connected to the core die; a host die electrically connected to the buffer die and including a processor; and a power management integrated circuit that provides an operating voltage to the core die. The host die further includes a power on self-test (POST) circuit that generates a self-test start request in response to receiving the boot signal from the processor. The buffer die includes a built in self-test (BIST) circuit that performs a self-test on the memory cell according to a test pattern and transmits a self-test result to POST circuit, in response to receiving the self-test start request from the POST circuit. The POST circuit transmits the self-test result to the processor, and the processor determines the operating voltage of the core die based on the self-test result.

Some example embodiments of the inventive concepts still further provide a semiconductor system that includes a package substrate; a host die on the package substrate; a plurality of core dies on the host die, the plurality of core dies electrically connected to the host die and including a memory cell; and a power management integrated circuit that provides an operating voltage to the plurality of core dies. The host die includes a self-test circuit that performs a self-test on the memory cell included in the plurality of core dies at one or more voltage levels according to a test pattern, and outputs a self-test result based on the self-test, in response to receiving a boot signal; and a processor that determines a minimum operating voltage of the plurality of core dies based on the self-test result.

According to some example embodiments, after completion of manufacturing, that is during actual use of the semiconductor system, it is possible to determine the operating voltage of the core die at every booting, thereby limiting and/or preventing unnecessary margins from being included in the operating voltage and reducing (and/or minimizing) power consumption.

According to some example embodiments, it is possible to dynamically adjust the operating voltage of the core die based on the output of various configurations in the semiconductor system, thereby providing an appropriate operating voltage to the core die and/or improving the reliability of the semiconductor device.

The effects of the present disclosure are not limited to the effects described above, and other effects not described herein should be understood from the following description and the claims.

### BRIEF DESCRIPTION OF THE DRAWINGS

The above and other objects, features and advantages of the present disclosure will be described with reference to the accompanying drawings described below, where similar reference numerals indicate similar elements, but are not limited thereto, in which:

FIG. 1 is a block diagram illustrating a semiconductor system according to some example embodiments of the inventive concepts;

FIG. 2 is a block diagram illustrating a semiconductor system to according to some example embodiments;

FIG. 3 is a diagram illustrating an example of a signal flow in a process of determining a minimum operating voltage of a core die according to some example embodiments;

FIG. 4 is a diagram provided to explain an example of an internal configuration of a POST circuit according to some example embodiments;

FIGS. 5 and 6 are flowcharts illustrating some example embodiments of a method for determining a minimum operating voltage of the core die;

FIG. 7 is a diagram illustrating an example of a signal flow in a process of determining a minimum operating voltage of the core die according to some example embodiments;

FIG. 8 is a block diagram illustrating a semiconductor system according to some example embodiments;

FIG. 9 is a diagram illustrating an example of a signal flow in a process of adjusting an operating voltage of the core die according to some example embodiments;

FIG. 10 is a diagram illustrating an example of a signal flow in a process of adjusting an operating voltage of the core die according to some example embodiments;

FIGS. 11 and 12 are block diagrams illustrating semiconductor systems according to some example embodiments;

FIG. 13 is a block diagram illustrating a semiconductor system according to some example embodiments;

FIG. 14 is a diagram illustrates a semiconductor package according to some example embodiments;

FIG. 15 is a diagram illustrating an implementation of the semiconductor package according to some example embodiments; and

FIG. 16 illustrates a semiconductor package according to some example embodiments.

### DETAILED DESCRIPTION

Hereinafter, some example embodiments of the present disclosure will be described in detail with reference to the accompanying drawings. However, in the following description, detailed descriptions of well-known functions or configurations may be omitted for the sake of brevity.

When the phrase “at least one of A, B, and C” and similar language (e.g., “at least one selected from the group consisting of A, B, and C”) are used in this specification, it is intended that it may be construed as A only, B only, C only, or any combination of two or more of A, B, and C, such as, for instance, ABC, AB, BC, and AC.

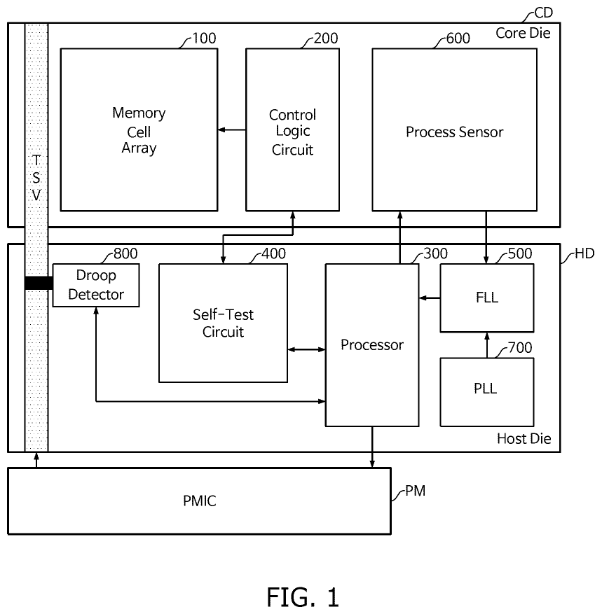

FIG. 1 is a block diagram illustrating an example of a semiconductor system according to some example embodiments. Referring to FIG. 1, the semiconductor system may include a core die CD, a host die HD electrically connected to the core die CD, and a power management integrated circuit PM.

The core die CD may be a memory device including a memory cell in which data is stored. The core die CD may operate under an operating voltage VDDC provided from the power management integrated circuit PM. The semiconductor system may include a high bandwidth memory (HBM) device including a plurality of core dies CD. For example, the semiconductor system may include a high-bandwidth stacked memory device in which the plurality of core dies CD are disposed on top of each other in a stack form. The semiconductor system may include a memory device operating according to the Joint Electron Device Engineering Council (JEDEC) standard, but is not limited thereto.

The core die CD may include a memory cell array 100, a control logic circuit 200, etc. The memory cell array 100 may include memory cells. The memory cell array 100 may include dynamic memory cells. For example, the core die CD may include a volatile memory device including dynamic memory cells. For example, the core die CD may include dynamic random access memory (DRAM), synchronous DRAM (SDRAM), etc., but is not limited thereto. According to some example embodiments, the core die CD may include a non-volatile memory device.

The control logic circuit 200 may receive an address, a command, a control signal, etc. from the outside of the core die CD, and may transmit and receive data to and from devices outside the core die CD. For example, the control logic circuit 200 may include a control logic, a row decoder, a page buffer, etc. When performing a memory operation such as a read operation, a program operation, an erase operation, etc., the control logic circuit 200 may adjust voltage levels provided to word lines and bit lines connected to the memory cell array 100. For example, when performing the program operation, the control logic circuit 200 may apply, to the bit line, a voltage according to data to be stored in the memory cell array 100. When performing a read operation, the control logic circuit 200 may detect the data stored in the memory cell array 100.

The host die HD may include a processor 300. The processor 300 may control the overall operation of the semiconductor system. For example, the processor 300 may control operations of respective components included in the semiconductor system. The processor 300 may be implemented as a general-purpose processor, and/or may be implemented as a dedicated processor, an application processor, etc. The processor 300 may include one or more CPUs.

The processor 300 may further include an accelerator block which is a dedicated circuit for high-speed data operation such as artificial intelligence (AI) data operation. The accelerator block may include a computational block such as a graphic processing unit (GPU), a neural processing unit (NPU), and/or a data processing unit (DPU). The accelerator block may be included in the processor 300 and/or implemented as a separate physically independent chip.

The processor 300 may determine an operating voltage (e.g., minimum operating voltage, adjusted operating voltage, etc.) of the core die CD. For example, the processor 300 may determine the operating voltage of the core die CD based on signals, information, data, etc. received from other components (e.g., a self-test circuit 400, a frequency-locked loop (FLL) circuit 500, a droop detector 800, etc.) in the semiconductor system. The processor 300 may control the power management integrated circuit PM so that the determined operating voltage is provided to the core die CD. The operating voltage of the core die CD may be an operating voltage associated with the configuration (e.g., the memory cell array 100) included in the core die CD. Additionally or alternatively, the operating voltage of the core die CD may be associated with a voltage supplied to the core die CD or may be associated with a voltage output from the power management integrated circuit PM.

The power management integrated circuit (PMIC) PM may provide power and voltage to each component of the semiconductor system. For example, the power management integrated circuit PM may provide the operating voltage to the core die CD. The operating voltage provided from the power management integrated circuit PM may be transmitted to the core die CD through a through via (e.g., Through Silicon Via (TSV)) formed in the host die HD and the core die CD. The through via through which the operating voltage is transmitted may be a power through via. The power through via may be a configuration formed separately from the signal through via.

The power management integrated circuit PM may receive information on the operating voltage of the core die CD from the processor 300 and provide the operating voltage to the core die CD based on the received information. Additionally or alternatively, the power management integrated circuit PM may receive the information on the operating voltage of the core die CD from other configurations within the semiconductor system and provide the operating voltage to the core die CD based on the received information.

The semiconductor system may determine the minimum operating voltage of the core die CD on (e.g., at) every booting (e.g., at every time the semiconductor system is booted). For example, the semiconductor system may perform a self-test on the memory cell of the core die CD on every booting, and determine the minimum operating voltage of the core die CD based on the self-test result. The minimum operating voltage of the semiconductor system may vary according to how many times the semiconductor system boots. For example, the minimum operating voltage determined on 100th booting and the minimum operating voltage determined on 1,000th booting may be different from each other.

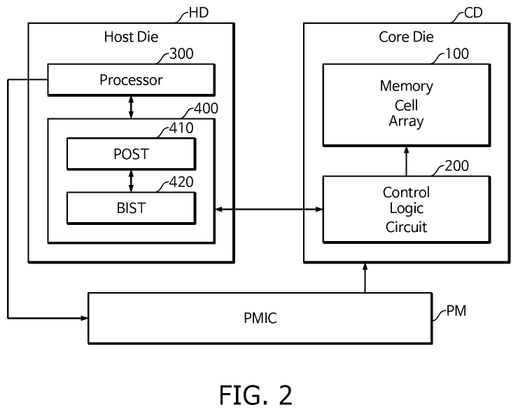

The host die HD may further include the self-test circuit 400. In response to the semiconductor system booting, the self-test circuit 400 may perform a self-test on the memory cell of the core die CD at one or more voltage levels and output the self-test result. The semiconductor system may determine the minimum operating voltage of the core die CD based on the self-test result. This will be described in more detail below with reference to FIGS. 2 to 7.

The semiconductor system may be affected by various external or internal factors during operation. The semiconductor system may include a configuration for monitoring these factors or subsequent changes in operation caused by the same. The semiconductor system may include a configuration for compensating for the changes in operation caused by the various factors. Monitoring the change in operation and compensating for the changes in operation may be dynamically executed.

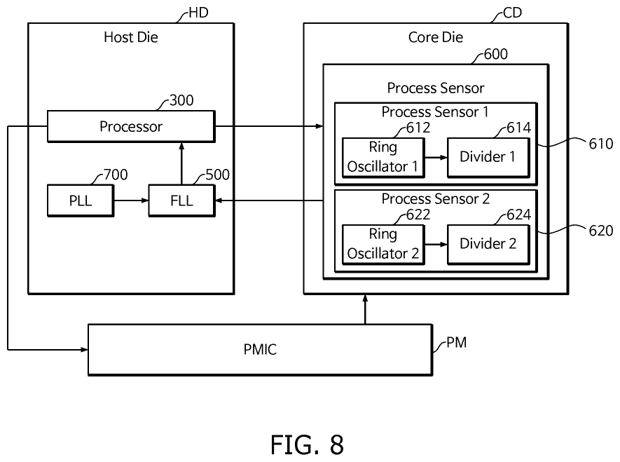

The semiconductor system may adjust the operating voltage of the core die CD based on outputs of various configurations in the semiconductor system. For example, the core die CD may further include a process sensor 600. The process sensor 600 may generate a process clock signal associated with an operating frequency of the memory cell. The host die HD may further include a frequency-locked loop (FLL) circuit 500 and/or a phase-locked loop (PLL) circuit 700. The PLL circuit 700 may generate a reference clock signal associated with a target frequency. The FLL circuit 500 may generate a result of frequency comparison based on the clock signal generated by the process sensor 600 and/or the clock signal generated by the PLL circuit 700. The semiconductor system may adjust the operating voltage of the core die CD based on the result of frequency comparison generated by the FLL circuit 500. This will be described in more detail below with reference to FIGS. 8 to 10.

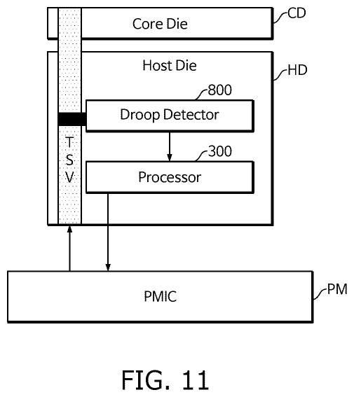

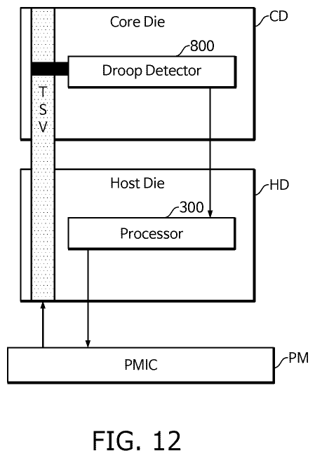

Additionally or alternatively, the host die HD and/or the core die CD may further include the droop detector 800. The droop detector 800 may detect a drop in the operating voltage transmitted through the through via TSV, and output voltage drop information. The semiconductor system may adjust the operating voltage of the core die CD based on the voltage drop information. This will be described in more detail below with reference to FIGS. 11 and 12.

According to a comparative example, in the test operation of the manufacturing process (post-process), various margins may be added to the minimum operating voltage so that the operating voltage of the core die CD may be determined. Once the operating voltage is determined, it may be continuously used regardless of the number of times the booting occurs, or the operation state. Alternatively, in some example embodiments of the inventive concepts, after completion of manufacturing, that is, during actual use of the semiconductor system, it is possible to determine a reduced and/or minimum operating voltage of the core die CD and/or adjust the operating voltage of the core die CD based on the outputs of various configurations in the semiconductor system on or at every booting. Accordingly, various margins included in the operating voltage of the core die CD may be reduced (and/or minimized), and power consumption may be saved, reduced and/or minimized. Various memory operations including read, write and/or erase operations for example may subsequently be performed at the core die CD based on the determined reduced and/or minimum operation voltage, enabling efficient and/or extended operation of the semiconductor system while reducing power consumption.

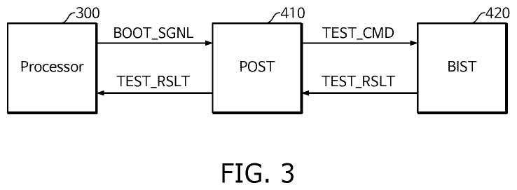

FIG. 2 is a block diagram illustrating a semiconductor system, and FIG. 3 is a diagram illustrating an example of a signal flow in a process of determining the minimum operating voltage of the core die CD according to some example embodiments. Referring to FIG. 2, the core die CD may include the memory cell array 100 including memory cells, and the control logic circuit 200, and the host die HD may include the processor 300 and the self-test circuit 400.

In response to receiving a boot signal, the self-test circuit 400 may perform a self-test on the memory cell at one or more voltage levels according to a desired (and/or alternatively predetermined) test pattern and output the self-test result. The processor 300 may determine the minimum operating voltage of the core die CD based on the self-test result, and control the power management integrated circuit PM such that the determined minimum operating voltage is provided to the core die CD.

For example, referring to FIGS. 2 and 3, the self-test circuit 400 may include a power-on self-test (POST) circuit 410 and a built-in self-test (BIST) circuit 420. The BIST circuit 420 may be included in the memory controller, but some example embodiments are not limited thereto.

In response to receiving the boot signal BOOT_SGNL from the processor 300, the POST circuit 410 may transmit a self-test start request TEST_CMD to the BIST circuit 420.

In response to receiving the self-test start request TEST_CMD from the POST circuit 410, the BIST circuit 420 may perform a self-test on the memory cell according to a desired (and/or alternatively predetermined) test pattern (e.g., a march pattern, a checkerboard pattern, and/or a random pattern, etc.). For example, the BIST circuit 420 may transmit, to the control logic circuit 200, a command for repeating a write operation, a read operation, etc. with respect to the memory cell according to a desired (and/or alternatively predetermined) test pattern. The BIST circuit 420 may acquire a detection signal indicating the operation state of the memory cell and generate a self-test result TEST_RSLT based on the detection signal. For example, the BIST circuit 420 may determine whether the memory cell operates normally based on the detection signal received from the control logic circuit 200. The BIST circuit 420 may generate a self-test result TEST_RSLT indicating whether the test is successful based on the determination on whether the memory cell operates normally. The BIST circuit 420 may transmit the generated self-test result TEST_RSLT to the POST circuit 410.

The POST circuit 410 may transmit the self-test result TEST_RSLT received from the BIST circuit 420 to the processor 300. Based on the received self-test result TEST_RSLT, the processor 300 may determine a direction of adjusting the voltage level provided to the core die CD. For example, the processor 300 may determine to adjust the voltage level provided to the core die CD upward or downward based on whether the test is successful or not as indicated by the self-test result. The processor 300 may control the power management integrated circuit (PM) to provide an operating voltage at the adjusted voltage level to the core die CD. The self-test process described above may be repeatedly performed at the adjusted voltage level. The operation of determining the direction of adjusting the voltage level provided to the core die CD based on the self-test result TEST_RSLT, and the operation of controlling the power management integrated circuit PM to provide an operating voltage of the adjusted voltage level to the core die CD may be performed by the POST circuit 410.

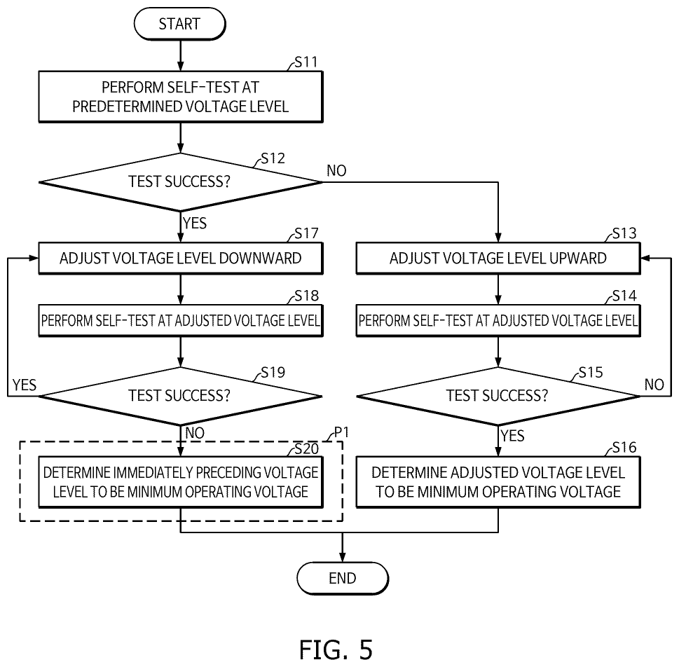

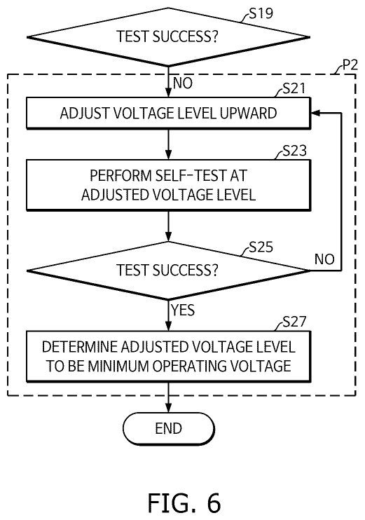

The minimum operating voltage of the core die CD may be determined based on a result of repeatedly performing the self-test process described above at one or more voltage levels. A method for adjusting the voltage level provided to the core die CD and determining the minimum operating voltage of the core die CD will be described in more detail with reference to FIGS. 5 and 6.

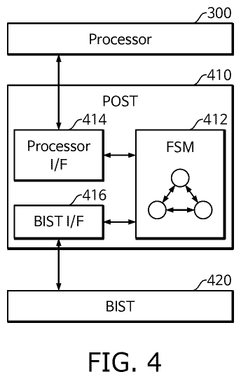

FIG. 4 is a diagram provided to explain an example of an internal configuration of the POST circuit 410 according to some example embodiments. Referring to FIG. 4, the POST circuit 410 may include a finite state machine (FSM) 412, a processor interface 414, and a BIST interface 416. The POST circuit 410 may communicate (e.g., transmit and receive signals, instructions, data, etc.) with the processor 300 using the processor interface 414, and may communicate with the BIST circuit 420 using the BIST interface 416.

The finite state machine 412 may indicate a state for a self-test. For example, the finite state machine 412 may represent the state for the self-test as one of the desired (and/or alternatively predetermined) states (e.g., test start, test failure, test success, idle state, etc.). The finite state machine 412 may transition the state for the self-test based on signals, instructions, and/or data, etc. received from the processor 300 and/or the BIST circuit 420.

For example, the finite state machine 412 may transition the state for the self-test to the test start state in response to the POST circuit 410 receiving the boot signal. The POST circuit 410 may transmit a self-test start request to the BIST circuit 420 using the BIST interface 416 in response to the transition of the state for the self-test to the test start state. As another example, the finite state machine 412 may transition the state for the self-test to the test success and failure state in response to the POST circuit 410 receiving a self-test result indicating test success and failure. The POST circuit 410 may transmit a self-test result indicating the test success and failure to the processor 300 using the processor interface 414 in response to the transition of the state for the self-test to the test success and failure state.

As another example, the POST circuit 410 may determine the direction of adjusting the voltage level provided to the core die CD in response to the transition of the state for the self-test to the test success and failure state. In some example embodiments, the POST circuit 410 may transmit a control signal for controlling the core die CD to provide an operating voltage of the adjusted voltage level to the power management integrated circuit PM.

FIGS. 5 and 6 are flowcharts illustrating some examples of a method for determining a reduced (and/or minimum) operating voltage of the core die according to some example embodiments. Referring to FIG. 5, first, a self-test may be performed at a desired (and/or alternatively predetermined) voltage level in response to the system booting, at S11. For example, the self-test may start at a desired (and/or alternatively predetermined) voltage level. For example, in response to the system booting, the processor 300 may control the power management integrated circuit PM to provide an operating voltage at a desired (and/or alternatively predetermined) voltage level (e.g., a start voltage level) to the core die CD, and transmit a boot signal to the self-test circuit 400. The self-test circuit 400 may perform the self-test in response to receiving the boot signal. For example, the self-test circuit 400 may perform the self-test while the operating voltage of the desired (and/or alternatively predetermined) voltage level to the core die CD is provided. The self-test circuit 400 may generate a self-test result at a desired (and/or alternatively predetermined) voltage level.

The desired (and/or alternatively predetermined) voltage level may be a voltage level within a voltage range defined in the standard specification associated with the semiconductor system. For example, the desired (and/or alternatively predetermined) voltage level may be the minimum voltage level of the VDDC specified in the JEDEC standard specification, but is not limited thereto. Additionally or alternatively, the desired (and/or alternatively predetermined) voltage level may be associated with the operating voltage of the core die at the recent power off point of the semiconductor system. For example, in response to receiving the power-off signal, the semiconductor system may store, in storage, the operating voltage (hereinafter referred to as the power-off voltage level) of the core die at that point. In some example embodiments, the desired (and/or alternatively predetermined) voltage level, which is the start voltage level of the self-test, may be determined based on the power-off voltage level stored in the storage.

The direction of adjusting the voltage level may be determined according to whether the test is successful or not as indicated by the self-test result at the desired (and/or alternatively predetermined) voltage level, at S12.

At S12, if (e.g., in response to) the self-test result at the desired (and/or alternatively predetermined) voltage level indicates a test failure, the voltage level may be adjusted upward, at S13. For example, the processor 300 may adjust the voltage level upward by a first desired (and/or alternatively predetermined) value (e.g., 0.05 [V]) in response to determining that the self-test result at the desired (and/or alternatively predetermined) voltage level indicates a test failure. The processor 300 may control the power management integrated circuit PM such that the operating voltage of the upward-adjusted voltage level is provided to the core die CD.

The self-test may be performed at the upward-adjusted voltage level, at S14. The process of performing the self-test may be performed similarly to the process described above. The voltage level may be adjusted upward or the minimum operating voltage may be determined according to whether the test is successful or not as indicated by the self-test result at the upward-adjusted voltage level, at S15.

At S15, if the self-test result at the upward-adjusted voltage level indicates a test failure, the voltage level may be adjusted upward again at S13, and the self-test may be performed again at the upward-adjusted voltage level at S14.

At S15, if the self-test result at the upward-adjusted voltage level indicates a test success, it may be determined that the corresponding voltage level is the minimum operating voltage of the core die at S16, and the method for determining the minimum operating voltage of the core die may be terminated. For example, in response to determining that the self-test result at the upward-adjusted voltage level indicates a test success, the processor 300 may determine the corresponding voltage level is the minimum operating voltage of the core die and transmit a test termination signal to the self-test circuit. The control logic circuit 200 may subsequently perform a memory operation such as a read, write and/or erase operation based on the determined reduced and/or minimum operating voltage to reduce and/or minimize power consumption.

Alternatively, at S12, if the self-test result at the desired (and/or alternatively predetermined) voltage level indicates a test success, the voltage level may be adjusted downward at S17. For example, the processor 300 may adjust the voltage level downward by a second desired (and/or alternatively predetermined) value (e.g., 0.1 [V]) in response to determining that the self-test result at the desired (and/or alternatively predetermined) voltage level indicates a test success. The processor 300 may control the power management integrated circuit PM such that the operating voltage of the downward-adjusted voltage level is provided to the core die.

The self-test may be performed at the downward-adjusted voltage level, at S18. The process of performing the self-test may be performed similarly to the process described above. The voltage level may be adjusted downward or the minimum operating voltage may be determined according to whether the test is successful or not as indicated by the self-test result at the downward-adjusted voltage level, at S19.

At S19, if the self-test result at the downward-adjusted voltage level indicates a test success, the voltage level may be adjusted downward again at S17, and the self-test may be performed again at the downward-adjusted voltage level at S18.

According to some example embodiments as indicated by (P1), if the self-test result at the downward-adjusted voltage level indicates a test failure at S19, it may be determined that the immediately preceding voltage level (e.g., the highest voltage level at which the self-test was successful) is the minimum operating voltage of the core die at S20, and the method for determining the minimum operating voltage of the core die may be terminated. For example, the processor 300 may determine that the immediately preceding voltage level is the minimum operating voltage of the core die in response to determining that the self-test result at the downward-adjusted voltage level indicates a test failure. The processor 300 may control the power management integrated circuit PM such that the determined minimum operating voltage is provided to the core die, and may transmit a test termination signal to the self-test circuit.

Alternatively, and according to some other example embodiments, if the self-test result at the downward-adjusted voltage level indicates a test failure at S19, the self-test may be performed again at the upward-adjusted voltage level. For example, referring to FIG. 6, in some example embodiments as indicated by P2, if the self-test result at the downward-adjusted voltage level indicates a test failure, the voltage level may be adjusted upward at S21. For example, the processor 300 may adjust the voltage level upward by a third desired (and/or alternatively predetermined) value (e.g., 0.05 [V]) in response to determining that the self-test result at the downward-adjusted voltage level indicates a test failure. The third desired (and/or alternatively predetermined) value may be less than the second desired (and/or alternatively predetermined) value used to downward-adjust the voltage level at S17 of FIG. 5. The processor 300 may control the power management integrated circuit such that the operating voltage of the upward-adjusted voltage level is provided to the core die.

The self-test may be performed at the upward-adjusted voltage level, at S23. The process of performing the self-test may be performed similarly to the process described above. The voltage level may be adjusted upward or the minimum operating voltage may be determined according to whether the test is successful or not as indicated by the self-test result at the upward-adjusted voltage level, at S25.

At S25, if the self-test result at the upward-adjusted voltage level indicates a test failure, the voltage level may be adjusted upward again at S21, and the self-test may be performed again at the upward-adjusted voltage level at S23.

At S25, if the self-test result at the upward-adjusted voltage level indicates a test success, it may be determined that the corresponding voltage level is the minimum operating voltage of the core die at S27, and the method for determining the minimum operating voltage of the core die may be terminated. The method for determining the minimum operating voltage of the core die described above with reference to FIGS. 5 and 6 may be performed every time the system boots.

The flowcharts of FIGS. 5 and 6 and the above description are merely examples, and some example embodiments are not limited thereto. According to some example embodiments, at least some operations may be added, removed, and changed, the order of at least some of the operations may be changed, or the subject that performs at least some of the operations may be changed.

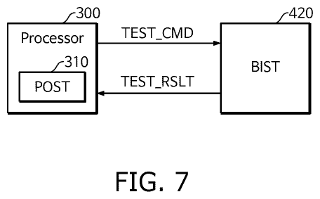

FIG. 7 is a diagram illustrating an example of a signal flow in a process of determining the reduced (and/or minimum) operating voltage of the core die CD according to some example embodiments. Referring to FIG. 7, the processor 300 may include a POST module 310, and the POST module 310 included in the processor 300 may perform the function of the POST circuit 410 described above with reference to FIGS. 2 to 6.

For example, the POST module 310 of the processor 300 may transmit a self-test start request TEST_CMD to the BIST circuit 420 in response to the system booting.

In response to receiving the self-test start request TEST_CMD, the BIST circuit 420 may perform a self-test on the memory cell according to a desired (and/or alternatively predetermined) test pattern and generate a self-test result TEST_RSLT. The BIST circuit 420 may transmit the generated self-test result TEST_RSLT to the processor 300.

The POST module 310 may determine the direction of adjusting the voltage level provided to the core die CD based on the self-test result TEST_RSLT received from the BIST circuit 420. The POST module 310 may control the power management integrated circuit PM to provide the operating voltage at the adjusted voltage level to the core die CD. The self-test process described above may be repeatedly performed at the adjusted voltage level. The POST module 310 may determine the minimum operating voltage of the core die CD based on a result of repeatedly performing the self-test process described above at one or more voltage levels.

FIG. 8 is a block diagram illustrating an example of the semiconductor system according to some example embodiments. Referring to FIG. 8, the core die CD may include the process sensor 600, and the host die HD may include the processor 300, the FLL circuit 500, and the PLL circuit 700.

The process sensor 600 may generate a process clock signal associated with the operating frequency of the memory cell and/or a peripheral circuit (e.g., control logic circuit, etc.) of the core die CD. The process sensor 600 may include ring oscillators 612 and 622 designed to generate a clock signal corresponding to the operating frequency of the memory cell of the core die CD. For example, the ring oscillators 612 and 622 may include an inverter chain including a plurality of inverters. Each inverter included in the inverter chain may use the output of the previous inverter as an input, and a clock signal may be generated through such feedback. The process sensor 600 may further include dividers 614 and 624 that reduce the frequency of the clock signal generated by the ring oscillators 612 and 622. Even under the same operating voltage, the frequency of the process clock signal generated by the process sensor 600 may vary according to environmental factors such as temperature.

The process sensor 600 may include a first process sensor 610 and a second process sensor 620. The first process sensor 610 and the second process sensor 620 may have the same or similar structure, but the second process sensor 620 may be used at a relatively lower frequency than the first process sensor 610. For example, the first process sensor 610 may be used at a relatively higher frequency, and the second process sensor 620 may be used at a relatively lower frequency. Difference in aging may occur over time between the two process sensors 610 and 620 having different usage frequencies. For this reason, the frequency of the process clock signal generated by the two process sensors 610 and 620 may be different even under the same conditions (e.g., the same operating voltage and the same environment).

The PLL circuit 700 may generate a reference clock signal associated with a target frequency. The PLL circuit 700 may be a circuit designed to generate a stable and accurate reference clock signal associated with a target frequency.

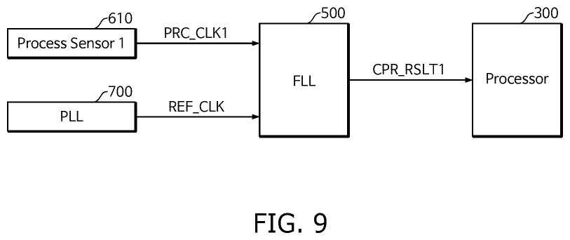

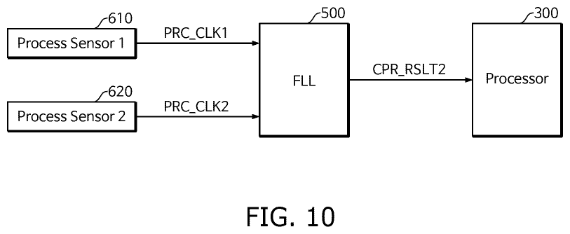

The FLL circuit 500 may generate a result of frequency comparison based on the process clock signal generated by the process sensor 600 and/or the reference clock signal generated by the PLL circuit 700. The processor 300 may adjust the operating voltage of the core die CD based on the result of frequency comparison generated by the FLL circuit 500. The processor 300 may control the power management integrated circuit PM such that the adjusted operating voltage is provided to the core die CD. This will be described below in more detail with reference to FIGS. 9 and 10.

FIG. 9 is a diagram illustrating an example of a signal flow in a process of adjusting the operating voltage of the core die. Referring to FIG. 9, the first process sensor 610 may generate a first process clock signal PRC_CLK1 associated with the operating frequency of the memory cell. The PLL circuit 700 may generate a reference clock signal REF_CLK associated with the target frequency. The FLL circuit 500 may generate a first result CPR_RSLT1 of frequency comparison based on the first process clock signal PRC_CLK1 and the reference clock signal REF_CLK. The first result CPR_RSLT1 of frequency comparison may include information on a difference between the frequency of the first process clock signal PRC_CLK1 and the frequency of the reference clock signal REF_CLK.

The processor 300 may receive the first result CPR_RSLT1 of frequency comparison from the FLL circuit 500 and adjust the operating voltage of the core die based on the first result CPR_RSLT1 of frequency comparison. For example, the processor 300 may determine to adjust the operating voltage upward and downward by the second desired (and/or alternatively predetermined) value based on determining that the difference between the frequency of the first process clock signal PRC_CLK1 and the frequency of the reference clock signal REF_CLK is greater than or equal to the first desired (and/or alternatively predetermined) value. As another example, the processor 300 may determine the operating voltage value of the core die to be adjusted, based on the first result CPR_RSLT1 of frequency comparison.

Unlike the comparative example in which the temperature margin is collectively added to the operating voltage of the core die in consideration of a speed decrease according to temperature, etc. in the test operation of the manufacturing process (post-process), according to some example embodiments of the inventive concepts, the operating voltage of the core die may be dynamically adjusted based on the clock signal generated by the first process sensor 610. Accordingly, the temperature margin may be optimized, power consumption may be saved, and/or reliability of the semiconductor system may be improved.

FIG. 10 is a diagram illustrating an example of a signal flow in a process of adjusting the operating voltage of the core die according to some example embodiments. Referring to FIG. 10, the first process sensor 610 may generate the first process clock signal PRC_CLK1 associated with the operating frequency of the memory cell. The second process sensor 620 may generate a second process clock signal PRC_CLK2 associated with the operating frequency of the memory cell. The second process sensor 620 may be a sensor that is used at a lower frequency than the first process sensor 610.

The FLL circuit 500 may generate a second result CPR_RSLT2 of frequency comparison based on the first process clock signal PRC_CLK1 and the second process clock signal PRC_CLK2. The second result CPR_RSLT2 of frequency comparison may include information on the difference between the frequency of the first process clock signal PRC_CLK1 and the frequency of the second process clock signal PRC_CLK2.

The processor 300 may receive the second result CPR_RSLT2 of frequency comparison from the FLL circuit 500 and adjust the operating voltage of the core die based on the second result CPR_RSLT2 of frequency comparison. For example, the processor 300 may determine to adjust the operating voltage upward and downward by the second desired (and/or alternatively predetermined) value based on determining that the difference between the frequency of the first process clock signal PRC_CLK1 and the frequency of the second process clock signal PRC_CLK2 is greater than or equal to the first desired (and/or alternatively predetermined) value. As another example, the processor 300 may determine the operating voltage value of the core die to be adjusted, based on the second result CPR_RSLT2 of frequency comparison.

Unlike the comparative example in which the aging margin is collectively added to the operating voltage of the core die in consideration of a performance degradation according to aging in the test operation of the manufacturing process, according to some example embodiments of the inventive concepts, the operating voltage of the core die may be dynamically adjusted based on the clock signals generated by the two process sensors 610 and 620 having different frequency of use. Accordingly, the aging margin may be optimized, power consumption may be saved, and/or reliability of the semiconductor system may be improved.

FIGS. 11 and 12 are block diagrams illustrating semiconductor systems according to some example embodiments. Referring to FIGS. 11 and 12, the semiconductor system may include the core die CD including the memory cell, the host die HD including the processor 300, and the power management integrated circuit PM providing the operating voltage to the core die CD. The core die CD and the host die HD may be electrically connected, and the operating voltage of the core die CD provided by the power management integrated circuit PM may be provided to the core die CD through the through vias formed in the host die HD and the core die CD. The through via through which the operating voltage is transmitted may be a power through via. The power through via may be a configuration formed separately from the signal through via.

The host die HD and/or the core die CD may include the droop detector 800. For example, as illustrated in FIG. 11, the host die HD may include the droop detector 800, and the droop detector 800 may be connected to the through via TSV formed in the host die HD. Additionally or alternatively, as illustrated in FIG. 12, the core die CD may include the droop detector 800, and the droop detector 800 may be connected to the through via TSV formed in the core die CD.

The droop detector 800 may detect a drop in the operating voltage transmitted through the through via TSV connected to the droop detector 800 and output voltage drop information. For example, the droop detector 800 may output the voltage drop information indicating that the drop in the operating voltage is detected. As another example, the droop detector 800 may output the voltage drop information indicating a degree of voltage drop.

The processor 300 may receive the voltage drop information output by the droop detector 800. The processor 300 may adjust the operating voltage of the core die CD based on the received voltage drop information. For example, the processor 300 may determine to adjust the operating voltage of the core die CD upward by a desired (and/or alternatively predetermined) value based on voltage drop information indicating that the drop in the operating voltage is detected. As another example, the processor 300 may determine the operating voltage value of the core die CD to be adjusted, based on the voltage drop information indicating the degree of voltage drop. The processor 300 may control the power management integrated circuit PM such that the adjusted operating voltage is provided to the core die CD.

Unlike the comparative example in which the voltage drop margin (IR drop margin) is collectively added to the operating voltage of the core die CD in the test operation of the manufacturing process, according to some example embodiments, the operating voltage of the core die CD may be dynamically adjusted based on the voltage drop information. Accordingly, the voltage drop margin may be optimized, power consumption may be saved, and/or reliability of the semiconductor system may be improved.

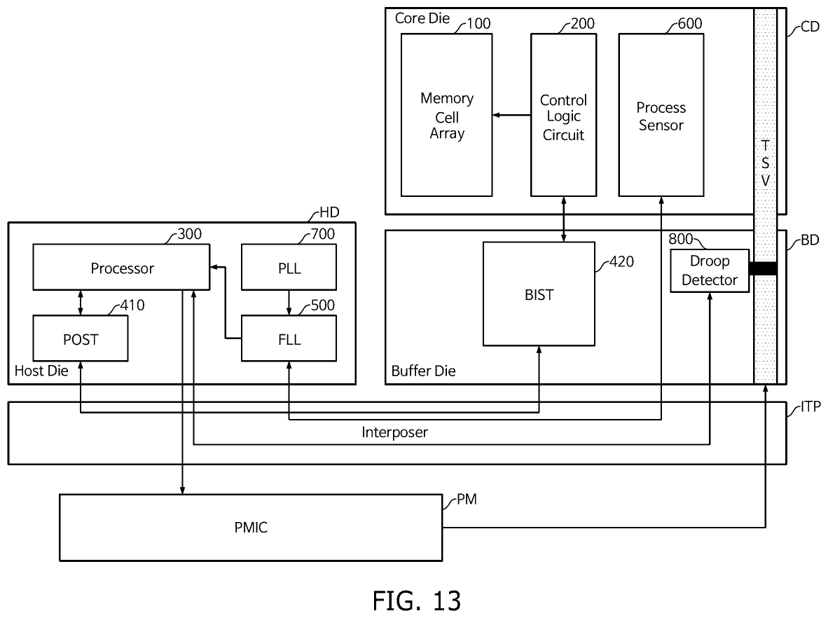

FIG. 13 is a block diagram illustrating an example of the semiconductor system according to some example embodiments of the inventive concepts. Referring to FIG. 13, the semiconductor system may include the core die CD, a buffer die BD electrically connected to the core die CD, the host die HD electrically connected to the buffer die BD through an interposer ITP, and the power management integrated circuit PM.

The core die CD may include the memory cell array 100, the control logic circuit 200, the process sensor 600, etc.

At least some of the components described as being included in the host die HD in some example embodiments described above with reference to FIGS. 1 to 12 may be included in the buffer die BD. For example, the host die HD may include the processor 300, the POST circuit 410, the FLL circuit 500, and the PLL circuit 700, and the buffer die BD may include the BIST circuit 420 and the droop detector 800. FIG. 13 is merely an example and some of the components may be implemented differently in some other example embodiments. For example, at least some of the components illustrated as being included in the host die HD may be included in the buffer die BD and/or the core die CD, or at least some of the components illustrated as being included in the buffer die BD may be included in the host die HD and/or the core die CD. As an example, the droop detector 800 may be included in the core die CD, and in some example embodiments, the droop detector 800 may be connected to the through via formed in the core die CD.

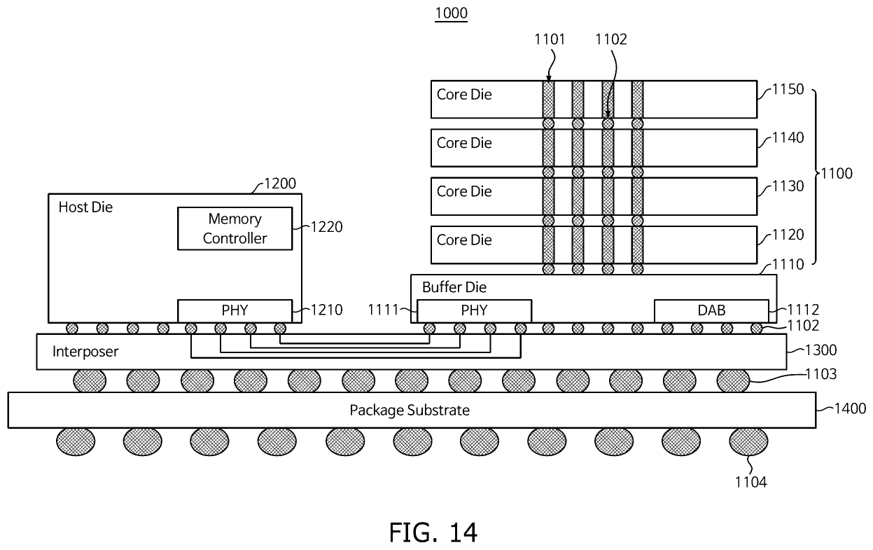

FIG. 14 is a diagram illustrating an example of a semiconductor package 1000. In some example embodiments, the semiconductor system may include the semiconductor package 1000. Referring to FIG. 14, the semiconductor package 1000 may include a stacked memory device 1100, a host die 1200, an interposer 1300, and a package substrate 1400. The stacked memory device 1100 may include a buffer die 1110 and core dies 1120 to 1150. Each of the core dies 1120 to 1150 may include a memory cell array. The buffer die 1110 may include a physical layer 1111 and direct access regions DAB 1112. The physical layer 1111 may be electrically connected to a physical layer 1210 of the host die 1200 through the interposer 1300. The stacked memory device 1100 may receive signals from the host die 1200 or transmit signals to the host die 1200 through the physical layer 1111. Signals, etc. may be transmitted and received through the physical layer 1111 while the self-test of the present disclosure is performed.

The direct access region 1112 may provide an access path to test the stacked memory device 1100 without passing through the host die 1200. The direct access region 1112 may include a conductive component (e.g., a port or a pin) capable of directly communicating with an external test device. The test signal and data received through the direct access region 1112 may be transmitted to the core dies 1120 to 1150 through the TSVs. Data read from the core dies 1120 to 1150 for testing the core dies 1120 to 1150 may be transmitted to the test device through the TSVs and the direct access region 1112. Accordingly, a direct access test may be performed on the core dies 1120 to 1150.

The buffer die 1110 and the core dies 1120 to 1150 may be electrically connected to each other through TSVs 1101 and bumps 1102. The buffer die 1110 may receive signals provided to each channel from the host die 1200 through the bumps 1102 allocated for each channel. For example, the bumps 1102 may be micro-bumps.

The host die 1200 may execute applications supported by the semiconductor package 1000 using the stacked memory device 1100. For example, the host die 1200 may include at least one processor such as a central processing unit (CPU), an application processor (AP), a graphic processing unit (GPU), a neural processing unit (NPU), a tensor processing unit (TPU), a vision processing unit (VPU), an image signal processor (ISP), and/or a digital signal processor (DSP) to execute specialized operations.

The host die 1200 may include the physical layer 1210 and a memory controller 1220. The physical layer 1210 may include input and output circuits for transmitting and receiving signals to and from the physical layer 1111 of the stacked memory device 1100. The host die 1200 may provide various signals to the physical layer 1111 through the physical layer 1210. The signals provided to the physical layer 1111 may be transmitted to the core dies 1120 to 1150 through interface circuits and the TSVs 1101 of the physical layer 1111.

The memory controller 1220 may control the overall operation of the stacked memory device 1100. The memory controller 1220 may transmit signals for controlling the stacked memory device 1100 to the stacked memory device 1100 through the physical layer 1210. Additionally or alternatively, the memory controller 1220 may be included in the buffer die 1110.

The interposer 1300 may connect the stacked memory device 1100 to the host die 1200. The interposer 1300 may connect the physical layer 1111 of the stacked memory device 1100 to the physical layer 1210 of the host die 1200, and may provide physical paths formed with conductive materials. Accordingly, the stacked memory device 1100 and the host die 1200 may be stacked on the interposer 1300 to transmit and receive signals to and from each other.

Bumps 1103 may be attached to an upper portion of the package substrate 1400, and a solder ball 1104 may be attached to a lower portion thereof. For example, the bumps 1103 may be flip-chip bumps. The interposer 1300 may be stacked on the package substrate 1400 through the bumps 1103. The semiconductor package 1000 may transmit and receive signals to and from other external packages or semiconductor devices through the solder ball 1104. For example, the package substrate 1400 may be a printed circuit board (PCB).

Although not shown, the semiconductor package 1000 may further include a power management integrated circuit, and the power management integrated circuit may be disposed on the package substrate 1400.

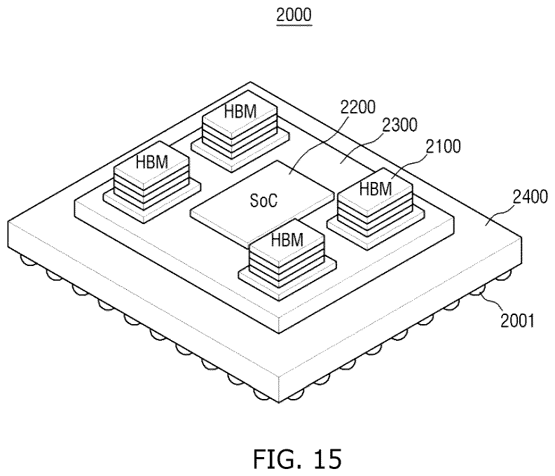

FIG. 15 is a diagram illustrating an example of implementation of a semiconductor package 2000. Referring to FIG. 15, the semiconductor package 2000 may include a plurality of stacked memory devices 2100 and a host die 2200. The stacked memory devices 2100 and the host die 2200 may be stacked on an interposer 2300, and the interposer 2300 may be stacked on a package substrate 2400. The semiconductor package 2000 may transmit and receive signals to and from other external packages or semiconductor devices through a solder ball 2001 attached to the lower portion of the package substrate 2400.

Each of the stacked memory devices 2100 may be implemented based on HBM standard. However, some example embodiments are not limited thereto, and each of the stacked memory devices 2100 may be implemented based on GDDR, HMC, or Wide I/O standard. Each of the stacked memory devices 2100 may correspond to the stacked memory device 1100 of FIG. 14.

The host die 2200 may be implemented as a system on chip (SoC) including at least one processor such as CPU, AP, GPU, NPU, etc. The host die 2200 may correspond to the host die 1200 of FIG. 14.

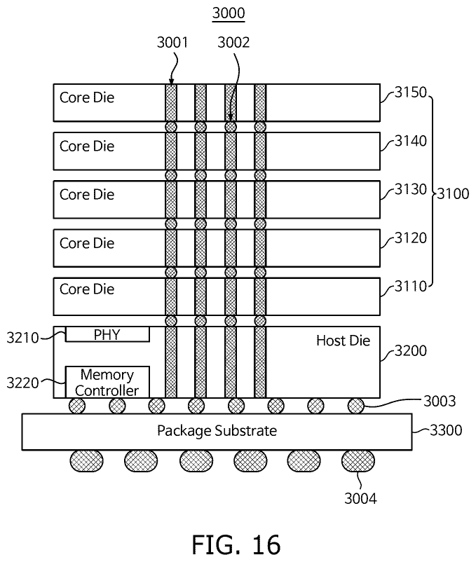

FIG. 16 is a diagram illustrating an example of a semiconductor package 3000. Referring to FIG. 16, the semiconductor package 3000 may include a stacked memory device 3100, a host die 3200, and a package substrate 3300. The stacked memory device 3100 may include core dies 3110 to 3150. Each of the core dies 3110 to 3150 may include a memory cell array. The semiconductor package 3000 may be a buffer-less semiconductor package. In some example embodiments, the host die 3200 may also perform the function of the buffer die. Alternatively, at least one (e.g., 3110 of FIG. 16) of the core dies 3110 to 3150 may be replaced with a buffer die.

The host die 3200 may include a physical layer 3210 for communicating with the stacked memory device 3100 and a memory controller 3220 for controlling the overall operation of the stacked memory device 3100. The host die 3200 may include a processor for controlling the overall operation of the semiconductor package 3000 and executing an application supported by the semiconductor package 3000. For example, the host die 3200 may include at least one processor such as CPU, AP, GPU, NPU, etc.

The stacked memory device 3100 may be disposed on the host die 3200 based on TSVs 3001 and may be vertically stacked on the host die 3200. Accordingly, the core dies 3110 to 3150 and the host die 3200 may be electrically connected to each other through the TSVs 3001 and bumps 3002 without an interposer. For example, the bumps 3002 may be micro-bumps.

Bumps 3003 may be attached to an upper portion of the package substrate 3300, and a solder ball 3004 may be attached to a lower portion thereof. For example, the bumps 3003 may be flip-chip bumps. The host die 3200 may be stacked on the package substrate 3300 through the bumps 3003. The semiconductor package 3000 may transmit and receive signals to and from other external packages or semiconductor devices through the solder ball 3004.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

Although not shown, the semiconductor package 3000 may further include a power management integrated circuit, and the power management integrated circuit may be disposed on the package substrate 3300.

Some example embodiments of the present disclosure have been described above for purposes of illustration only, and those skilled in the art with ordinary knowledge of the present disclosure will be able to make various modifications, changes and additions within the spirit and scope of the present disclosure, and such modifications, changes and additions should be construed to be included in a scope of the claims.

It should be understood that those of ordinary skill in the art to which the present disclosure pertains can make various substitutions, modifications and changes without departing from the technical spirit of the present disclosure, and thus, the present disclosure is not limited by some example embodiments described above and the accompanying drawings.

1. A semiconductor system, comprising:
a core die including a memory cell;
a host die electrically connected to the core die; and
a power management integrated circuit configured to provide an operating voltage to the core die,
wherein the host die comprises
a self-test circuit configured to perform a self-test on the memory cell at one or more voltage levels according to a test pattern and output a self-test result based on the self-test, in response to receiving a boot signal, and
a processor configured to determine a minimum operating voltage of the core die based on the self-test result.

2. The semiconductor system according to claim 1, wherein in response to booting of the semiconductor system, the processor is configured to control the power management integrated circuit such that a start voltage level is provided to the core die as the operating voltage and transmit the boot signal to the self-test circuit.

3. The semiconductor system according to claim 1, wherein the self-test circuit comprises:
a built in self-test (BIST) circuit configured to acquire from the core die a detection signal indicating an operating state of the memory cell at each of the one or more voltage levels and generate the self-test result based on the detection signal, in response to receiving a self-test start request; and
a power on self-test (POST) circuit configured to transmit the self-test start request to the BIST circuit and transmit the self-test result received from the BIST circuit to the processor, in response to receiving the boot signal from the processor.

4. The semiconductor system according to claim 3, wherein the POST circuit includes a finite state machine configured to represent a state for the self-test and transition the state for the self-test based on at least one of a signal received from the processor and the self-test result received from the BIST circuit.

5. The semiconductor system according to claim 1, wherein
the self-test circuit is configured to perform the self-test on the memory cell at a first voltage level from among the one or more voltage levels, and transfer a first self-test result to the processor,
the processor is configured to control the power management integrated circuit such that a second voltage level from among the one or more voltage levels that is lower than the first voltage level is provided to the core die as the operating voltage, in response to determining that the first self-test result indicates a test success, and
the self-test circuit is configured to perform the self-test on the memory cell at the second voltage level and transfer a second self-test result to the processor.

6. The semiconductor system according to claim 5, wherein the processor is configured to determine the first voltage level as the minimum operating voltage of the core die, and control the power management integrated circuit such that the first voltage level is provided to the core die as the operating voltage, in response to determining that the second self-test result indicates a test failure.

7. The semiconductor system according to claim 5, wherein
the processor is configured to control the power management integrated circuit such that a third voltage level from among the one or more voltage levels that is higher than the second voltage level and lower than the first voltage level is provided to the core die as the operating voltage, in response to determining that the second self-test result indicates a test failure, and
the self-test circuit is configured to perform the self-test on the memory cell at the third voltage level and transmit a third self-test result to the processor.

8. The semiconductor system according to claim 7, wherein in response to determining that the third self-test result indicates a test success, the processor is configured to determine the third voltage level as the minimum operating voltage of the core die, and control the power management integrated circuit such that the third voltage level is provided to the core die as the operating voltage.

9. The semiconductor system according to claim 1, wherein the core die further includes a process sensor configured to generate a process clock signal associated with an operating frequency of the memory cell, and
the host die further comprises:
a phase-locked loop (PLL) circuit configured to generate a reference clock signal associated with a target frequency; and
a frequency-locked loop (FLL) circuit configured to perform frequency comparison based on the process clock signal and the reference clock signal, and generate a first result based on the frequency comparison, and
the processor is configured to receive the first result of the frequency comparison, adjust the operating voltage of the core die based on the first result of frequency comparison to provide an adjusted operating voltage, and control the power management integrated circuit such that the adjusted operating voltage is provided to the core die as the operating voltage.

10. The semiconductor system according to claim 9, wherein the process sensor includes a ring oscillator configured to generate a clock signal corresponding to the operating frequency of the memory cell.

11. The semiconductor system according to claim 10, wherein the process sensor further includes a divider configured to reduce a frequency of the clock signal generated by the ring oscillator and provide the clock signal having reduced frequency as the process clock signal.

12. The semiconductor system according to claim 1, wherein the core die further comprises:
a first process sensor configured to generate a first process clock signal associated with an operating frequency of the memory cell; and
a second process sensor configured to generate a second process clock signal associated with the operating frequency of the memory cell at a lower frequency than the first process sensor,
the host die further including a frequency locked-loop (FLL) circuit configured to perform frequency comparison based on the first process clock signal and the second process clock signal, and generate a first result based on the frequency comparison, and
the processor is configured to receive the first result of the frequency comparison, adjust the operating voltage of the core die based on the first result of the frequency comparison to provide an adjusted operating voltage, and control the power management integrated circuit such that the adjusted operating voltage is provided to the core die as the operating voltage.

13. The semiconductor system according to claim 1, further comprising a through via in the host die and the core die,
wherein the power management integrated circuit is configured to provide the operating voltage to the core die through the through via.

14. The semiconductor system according to claim 13, wherein
the host die further includes a droop detector electrically connected to the through via in the host die, the droop detector configured to detect a drop in the operating voltage transferred through the through via and output voltage drop information in response to a detected drop in the operating voltage, and
the processor is configured to adjust the operating voltage of the core die based on the voltage drop information to provide an adjusted operating voltage, and control the power management integrated circuit such that the adjusted operating voltage is provided to the core die as the operating voltage.

15. The semiconductor system according to claim 13, wherein
the core die further includes a droop detector electrically connected to the through via in the core die, the droop detector configured to detect a drop in the operating voltage transferred through the through via and output voltage drop information in response to a detected drop in the operating voltage, and
the processor is configured to adjust the operating voltage of the core die based on the voltage drop information to provide an adjusted operating voltage, and control the power management integrated circuit such that the adjusted operating voltage is provided to the core die as the operating voltage.

16. A semiconductor system, comprising:
a core die including a memory cell;
a buffer die electrically connected to the core die;
a host die electrically connected to the buffer die and including a processor; and
a power management integrated circuit configured to provide an operating voltage to the core die, wherein
the host die further includes a power on self-test (POST) circuit configured to generate a self-test start request in response to receiving a boot signal from the processor,
the buffer die includes a built in self-test (BIST) circuit configured to perform a self-test on the memory cell according to a test pattern and transmit a self-test result to the POST circuit, in response to receiving the self-test start request from the POST circuit,
the POST circuit is configured to transmit the self-test result to the processor, and
the processor is configured to determine the operating voltage of the core die based on the self-test result.

17. The semiconductor system according to claim 16, wherein
the core die further includes a process sensor configured to generate a process clock signal associated with an operating frequency of the memory cell, and
the host die further comprises:
a phase locked-loop (PLL) circuit configured to generate a reference clock signal associated with a target frequency; and
a frequency locked-loop (FLL) circuit configured to perform frequency comparison based on the process clock signal and the reference clock signal, and generate a first result based on the frequency comparison, and
the processor is configured to receive the first result of the frequency comparison, adjust the operating voltage of the core die based on the first result of the frequency comparison to provide an adjusted operating voltage, and control the power management integrated circuit such that the adjusted operating voltage is provided to the core die as the operating voltage.

18. The semiconductor system according to claim 16, wherein the core die further comprises:
a first process sensor configured to generate a first process clock signal associated with an operating frequency of the memory cell; and
a second process sensor configured to generate a second process clock signal associated with the operating frequency of the memory cell at a lower frequency than the first process sensor,
wherein the host die further includes a frequency locked-loop (FLL) circuit configured to perform frequency comparison based on the first process clock signal and the second process clock signal, and generate a first result based on the frequency comparison, and
the processor is configured to receive the first result of the frequency comparison, adjust the operating voltage of the core die based on the first result of the frequency comparison to provide an adjusted operating voltage, and control the power management integrated circuit such that the adjusted operating voltage is provided to the core die as the operating voltage.

19. The semiconductor system according to claim 16, wherein
the power management integrated circuit is configured to provide the operating voltage to the core die through a through via in the buffer die and the core die,
the buffer die further includes a droop detector electrically connected to the through via in the buffer die, the droop detector configured to detect a drop in the operating voltage transferred through the through via and output voltage drop information in response to a detected drop in the operation voltage, and
the processor is configured to adjust the operating voltage of the core die based on the voltage drop information and control the power management integrated circuit such that the adjusted operating voltage is provided to the core die as the operating voltage.

20. A semiconductor system, comprising:
a package substrate;
a host die on the package substrate;
a plurality of core dies on the host die, the plurality of core dies electrically connected to the host die and including a memory cell; and
a power management integrated circuit configured to provide an operating voltage to the plurality of core dies,
wherein the host die comprises
a self-test circuit configured to perform a self-test on the memory cell included in the plurality of core dies at one or more voltage levels according to a test pattern, and output a self-test result based on the self-test, in response to receiving a boot signal, and
a processor configured to determine a minimum operating voltage of the plurality of core dies based on the self-test result.
